(19) United States
(12) Patent Application Publication
(10) Pub. No.: US 2016/0205790 A1
(43) Pub. Date: Jul. 14, 2016

(54) ELECTRONIC WHITEBOARD AND SHELL OF AN ELECTRONIC DEVICE

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: LI-FU XU, Wuhan (CN); CHUN-WEI YANG, Wuhan (CN); YONG-NIAN CHEN, Wuhan (CN); MING-CHUAN LEE, New Taipei (TW)

(21) Appl. No.: 14/602,768

(22) Filed: Jan. 22, 2015

(30) Foreign Application Priority Data
Jan. 9, 2015 (CN) 201510010678.2

(51) Int. Cl. H05K 5/00; H05K 5/02

(52) U.S. Cl. CPC H05K 5/0017; H05K 5/0247; H05K 5/0004

(57) ABSTRACT

An electronic whiteboard able to use any shell and any touchscreen includes a shell and a touch-screen. The touch-screen includes a cable. The shell includes a side plate and a bottom plate. The bottom plate is substantially perpendicular to the side plate. The side plate defines a receiving groove. The touch-screen is engaged with the bottom plate. The cable is received in the receiving groove. A shell of an electronic device is also provided.

### CROSS-REFERENCE TO RELATED APPLICATIONS

This application claims priority to Chinese Patent Application No. 201510010678.2 filed on Jan. 9, 2015, the contents of which are incorporated by reference herein.

### FIELD

The subject matter herein generally relates to an electronic whiteboard.

### BACKGROUND

An electronic whiteboard usually includes a shell and a touch-screen. The touch-screen includes a cable. The shell and the touch-screen are produced by different manufacturers and need to be coupled.

### BRIEF DESCRIPTION OF THE DRAWINGS

Implementations of the present technology will now be described, by way of example only, with reference to the attached figures.

FIG. 1 is an exploded, isometric view of one embodiment of an electronic whiteboard.

FIG. 2 is similar to FIG. 1, but viewed from another angle.

FIG. 3 is an enlarged view of circled portion III of FIG. 2.

FIG. 4 is an assembled, isometric view of the electronic whiteboard of FIG. 1.

FIG. 5 is an enlarged view of circled portion V of FIG. 4.

FIG. 6 is a partial, assembled, isometric view of the electronic whiteboard of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

The present disclosure is described in relation to an electronic whiteboard.

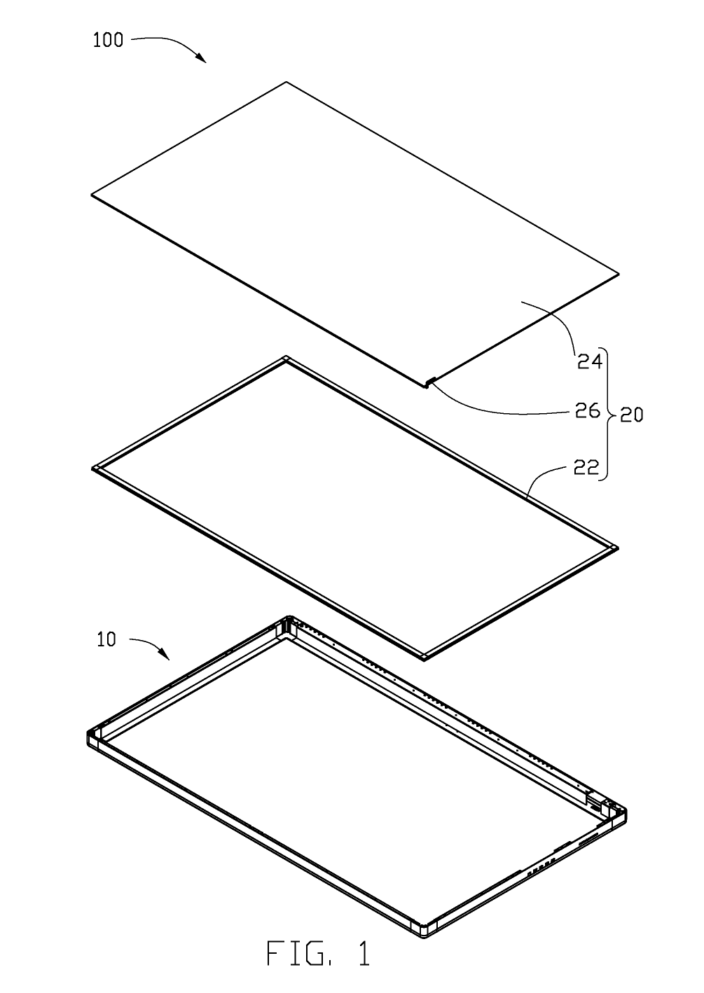

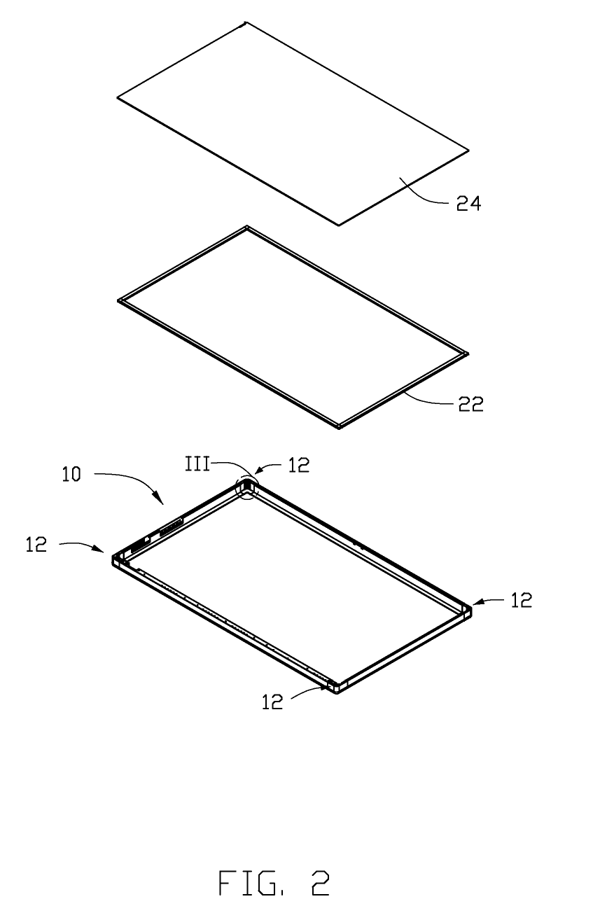

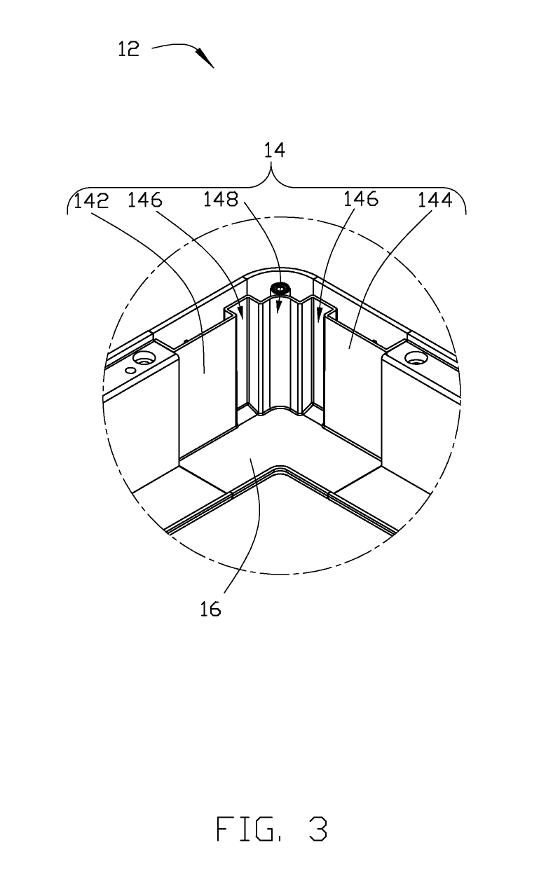

FIGS. 1-3 illustrate one embodiment of an electronic whiteboard 100. The electronic whiteboard 100 includes a shell 10 and a touch-screen 20.

The shell 10 includes four connecting portions 12. Each connecting portion 12 includes a side plate 14 and a bottom plate 16. The bottom plate 16 extends from the side plate 14 and is substantially perpendicular to the side plate 14. The side plate 14 includes a first side plate 142 and a second side plate 144. The second side plate 144 extends from the first side plate 142 and is substantially perpendicular to the first side plate 142. The side plate 14 defines two receiving grooves 146 and a mounting groove 148. The two receiving grooves 146 are located on either side of the mounting groove 148. The mounting groove 148 is located on the connection between the first side plate 142 and the second side plate 144. One of the two receiving grooves 146 is defined in the first side plate 142. Another receiving groove 146 is defined in the second side plate 144. The two receiving grooves 146 are formed as depressions in the first side plate 142 and the second side plate 144, away from the bottom plate 16. The two receiving grooves 146 and the mounting groove 148 extend to the bottom plate 16. An extending direction of the two receiving grooves 146 and the mounting groove 148 is substantially perpendicular to the bottom plate 16. In at least one embodiment, the shell 10 is substantially rectangular. The four connecting portions 12 are located on four corners of the shell 10. A cross section of the mounting groove 148 can be substantially arcuate. A cross section of each receiving groove 146 can be substantially U-shaped.

The touch-screen 20 includes a sensing component 22, a screen 24, and a cable 26. In at least one embodiment, the sensing component 22 is substantially a rectangular frame. An outline of the screen 24 is substantially equal to an outline of the sensing component 22.

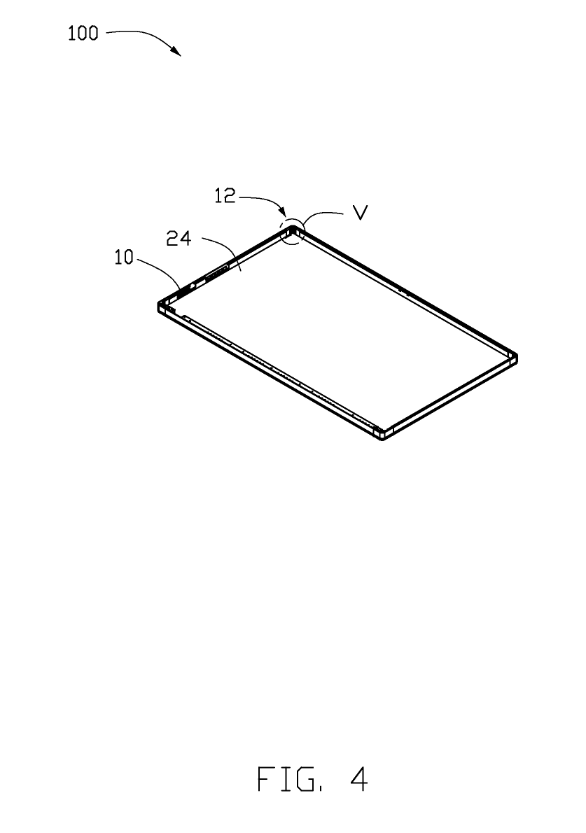

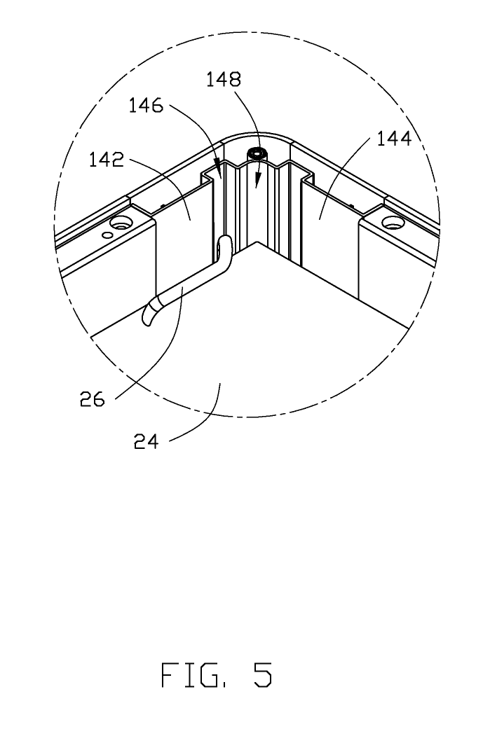

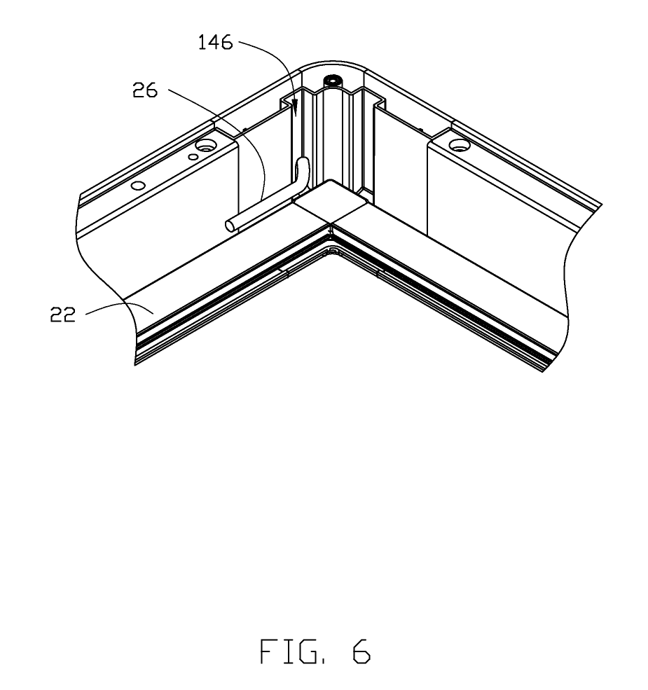

FIGS. 4-6 illustrate assembled views of the electronic whiteboard of FIG. 1. When the electronic whiteboard 100 is assembled, the sensing component 22 is engaged with the bottom plate 16. The screen 24 is engaged with the four mounting grooves 148. The screen 24 is engaged with the sensing component 22. One end of the cable 26 connects with the screen 24. The other end of the cable 26 is engaged with the receiving groove 146 and connects with the sensing component 22. The sensing component 22 and the screen 24 are engaged with the side plate 14. The cable 26 is partly received in the receiving groove 146. The touch-screen 20 (as shown in FIG. 1) is received in the shell 10.

The embodiments shown and described above are only examples. Many details are often found in the art such as the other features of an electronic whiteboard. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An electronic whiteboard comprising:
a shell comprising a side plate and a bottom plate, the bottom plate being substantially perpendicular to the side plate, and the side plate defining a receiving groove; and
a touch-screen comprising a cable;
wherein the touch-screen is engaged with the bottom plate, and the cable is received in the receiving groove.

2. The electronic whiteboard of claim 1, wherein the receiving groove is formed as a depression in the side plate, away from the bottom plate.

3. The electronic whiteboard of claim 2, wherein a cross section of the receiving groove is substantially U-shaped.

4. The electronic whiteboard of claim 1, wherein the touch-screen comprises a sensing component and a screen, the sensing component is substantially a rectangular frame, the screen is engaged with the sensing component, and the cable connects the sensing component and the screen.

5. The electronic whiteboard of claim 1, wherein the screen is engaged with the side plate.

6. The electronic whiteboard of claim 1, wherein the receiving groove extends in a direction that is substantially perpendicular to the bottom plate.

7. The electronic whiteboard of claim 1, wherein the side plate further defines a second receiving groove and a mounting groove, and the two receiving grooves are located on two sides of the mounting groove.

8. The electronic whiteboard of claim 7, wherein the side plate comprises a first side plate and a second side plate, the second side plate is substantially perpendicular to the first side plate, and the two receiving grooves are respectively located in the first side plate and the second side plate.

9. The electronic whiteboard of claim 7, wherein the mounting groove extends in a direction that is substantially perpendicular to the bottom plate.

10. The electronic whiteboard of claim 1, wherein the shell is substantially rectangular, the shell comprises four connecting portions, the four connecting portions are located on four corners of the shell, each connecting portion defines two receiving grooves.

11. A shell of an electronic device comprising:
a side plate defining a receiving groove; and
a bottom plate substantially perpendicular to the side plate;
wherein the receiving groove extends to the bottom plate, an extending direction of the receiving groove is substantially perpendicular to the bottom plate, and the receiving groove is adapted to receive a cable.

12. The shell of an electronic device of claim 11, wherein the receiving groove is formed as a depression in the side plate, away from the bottom plate.

13. The shell of an electronic device of claim 12, wherein a cross section of the receiving groove is substantially U-shaped.

14. The shell of electronic device of claim 12, wherein the side plate further defines a second receiving groove and a mounting groove, and the two receiving grooves are located on two sides of the mounting groove.

15. The shell of an electronic device of claim 14, wherein a cross section of the mounting groove is substantially arcuate.

16. The shell of an electronic device of claim 14, wherein an extending direction of the mounting groove is substantially perpendicular to the bottom plate.

17. The shell of an electronic device of claim 14, wherein the side plate comprises a first side plate and a second side plate, the second side plate is substantially perpendicular to the first side plate, and the two receiving grooves are respectively located in the first side plate and the second side plate.

18. The shell of an electronic device of claim 11, wherein the shell is substantially rectangular, the shell comprises four connecting portions, the four connecting portions are located on four corners of the shell, each connecting portion defines two receiving grooves.
